(19) United States
(12) Patent Application Publication
(10) Pub. No.: US 2026/0194245 A1
(43) Pub. Date: Jul. 9, 2026

(54) AIR CURTAIN DEVICE

(71) Applicant: GUDENG EQUIPMENT CO., LTD., New Taipei City (TW)

(72) Inventors: TSUNG-CHI HSIEH, New Taipei City (TW); LIN-HSIN TU, New Taipei City (TW); HUNG-CHE LAI, New Taipei City (TW); CHING-HSIEN HUANG, New Taipei City (TW)

(73) Assignee: GUDENG EQUIPMENT CO., LTD., New Taipei City (TW)

(21) Appl. No.: 19/262,148

(22) Filed: Jul. 8, 2025

Related U.S. Application Data
(60) Provisional application No. 63/742,871, filed on Jan. 8, 2025.

(51) Int. Cl. F24F 9/00; H10P 72/10

(52) U.S. Cl. CPC F24F 9/00; H10P 72/1922; H10P 72/1926; F24F 2009/007

(57) ABSTRACT

An air curtain device which is suitable for a loading device of a semiconductor carrier mainly includes a housing, and an air curtain assembly. An accommodating space in the housing is divided into a plurality of air equalizing chambers by means of a plurality of air diffusion members. The air curtain assembly is configured to receive air that passes through the air equalizing chambers; and after air is adjusted by the long and narrow space and an airflow of the two adjustable air curtains, a directional linear airflow is formed, and the linear airflow is suitable for blowing towards an opening of the semiconductor carrier. Therefore, when carrying a semiconductor element, fine dust and moisture can be prevented from invading the semiconductor carrier, thereby improving the storage quality of the semiconductor element as well as improving the yield of the manufacturing process.

### CROSS-REFERENCE TO RELATED APPLICATION

This non-provisional application claims priority under 35 U.S.C. § 119(e) on US provisional Patent Application No.63/742,871 filed on Jan. 8, 2025, the entire contents of which are hereby incorporated by reference.

### BACKGROUND OF THE INVENTION

### Field of the Invention

The present disclosure relates to an air curtain device, and in particular, to an air curtain device which is arranged at a gate of a loading device or a container opening and provides a directional and uniform linear airflow to blow towards a semiconductor carrier.

### Description of the Related Art

In the semiconductor manufacturing process, after a semiconductor carrier, such as a front opening unified pod (FOUP), carrying a semiconductor element moves to a load port, it is needed to open a door of the semiconductor carrier to transfer the semiconductor element, and at this moment, external fine dust or moisture can easily enter the semiconductor carrier and cause pollution to the semiconductor element, which affects the yield of the manufacturing process.

As the semiconductor manufacturing process becomes more advanced, the requirements for low fine dust pollution and moisture level in the environment are very high, and even trace amounts of fine dust or moisture may have a significant impact on the yield of the manufacturing process. The conventional technology for solving the above problem is to mount a jet device on the load port, and jet a large-scale flow of clean and dry air through air outlet grids outside an opening of the semiconductor carrier, so as to prevent the fine dust and moisture from entering the semiconductor carrier. However, the large-scale airflow that is downwards jetted will lead to turbulence and cause chaotic flow directions, which may be highly likely to draw in the external fine dust and air with high moisture into the semiconductor carrier to cause pollution, and consequently, the original purpose of blocking the fine dust and moisture from entering the semiconductor carrier cannot be achieved. Additionally, the conventional technology is also prone to causing windless zones and insufficient air volume concentration, resulting in ineffective interception, as well as energy loss and waste.

Therefore, how to provide a device that can be arranged at a gate of a loading device and can provide a directional and uniform linear airflow to improve the storage quality of the semiconductor element becomes crucial.

### BRIEF SUMMARY OF THE INVENTION

In view of this, the present disclosure provides an air curtain device which has the advantages of effectively outputting uniform and linear air with concentrated air volume, adjusting the airflow direction, reducing energy loss, reducing turbulence and dispersion of the airflow in the flowing direction and the like.

In an aspect, the present disclosure provides an air curtain device, suitable for a loading device of a semiconductor carrier. The air curtain device includes a housing and an air curtain assembly. The housing includes at least one air inlet, an accommodating space, and a plurality of air diffusion members, the air inlet being in communication with the accommodating space, and the plurality of air diffusion members dividing the accommodating space into a plurality of air equalizing chambers. The air curtain assembly is adjacently arranged in one of the air equalizing chambers of the housing and is defined as an air outlet. The air curtain assembly includes at least two adjustable air curtains on different horizontal planes, and the two adjustable air curtains are adjusted at a distance from each other to define a long and narrow space. The air curtain assembly is configured to receive air that passes through the air equalizing chambers; and after the air is adjusted by the long and narrow space and the two adjustable air curtains, a directional linear airflow is formed, and the linear airflow is suitable for blowing towards an opening of the semiconductor carrier.

In one embodiment, the air curtain device further includes at least one space adjusting member, arranged in the accommodating space, the space adjusting member being configured to adjust a range of the long and narrow space between the two adjustable air curtains.

In one embodiment, the two adjustable air curtains are provided with symmetrical slopes, lower edges of the slopes correspond to the long and narrow space in position, and a tapered structure is formed between the two adjustable air curtains and the air equalizing chambers.

In one embodiment, the two adjustable air curtains are respectively provided with at least two slopes with different jump, lower edges of the slopes correspond to the long and narrow space in position, and a tapered structure is formed between the two adjustable air curtains and the air equalizing chambers.

In one embodiment, the air diffusion member adjacent to the air curtain assembly is provided with symmetrical slopes so that an air volume of two air equalizing chambers divided by the air diffusion member is increased.

In one embodiment, the air curtain assembly further includes at least one auxiliary air curtain, arranged below at least one adjustable air curtain so as to present the two adjustable air curtains on different horizontal planes.

In one embodiment, two air diffusion members are provided and are arranged at an interval in the accommodating space, and a first air equalizing chamber, a second air equalizing chamber, and a third air equalizing chamber are sequentially divided from a position adjacent to the air inlet; air is diffused by each air diffusion member to form an air-equalized airflow and flows into the second air equalizing chamber and the third air equalizing chamber; and the air curtain assembly is adjacently arranged in the third air equalizing chamber.

In one embodiment, the third air equalizing chamber further includes an auxiliary air diffusion member so that the third air equalizing chamber is divided into two secondary air equalizing chambers.

In one embodiment, materials of the air diffusion members are selected from a sintered filter screen, a diffuser, or breathable filter cotton.

In one embodiment, the air curtain device further includes a plurality of air inlet elements configured in different directions and arranged on the housing, the air inlet elements being in communication with the air inlet to adjust different air inlet positions or air inflows.

According to the air curtain device in the present disclosure, the air supply mode of the air inlet can be adjusted in response to different air supply positions, functions, and strength. When supplied air is charged into the accommodating space of the housing by means of the air inlet, the air in the accommodating space is distributed by the air diffusion members, and after the airflow can be uniformly diffused in the air equalizing chambers, the same air distribution can be performed on the next layer of air equalizing chambers; and when the air flows to the air outlet, airflow adjustment is performed on the air by the adjustable air curtain assemblies on different horizontal planes and the long and narrow space defined by the adjustable air curtain assemblies, thus the outputted air can form the directional linear airflow, which can block the fine dust and air with high moisture outside the semiconductor carrier, thereby improving the storage quality of the semiconductor element as well as improving the yield of the manufacturing process.

### BRIEF DESCRIPTION OF THE DRAWINGS

FIG. 1 is a three-dimensional schematic diagram of an air curtain device in an embodiment of the present disclosure.

FIG. 2 is a three-dimensional schematic diagram of an air curtain device at another view angle in an embodiment of the present disclosure.

FIG. 3 is a three-dimensional schematic exploded configuration diagram of an air curtain device in an embodiment of the present disclosure.

FIG. 4 is a schematic sectional diagram along a section line 4-4 in FIG. 1.

FIG. 5 is a schematic sectional diagram along a section line 5-5 in FIG. 1.

FIG. 6 is a partial enlarged schematic diagram of an air outlet of an air curtain device in an embodiment of the present disclosure.

FIG. 7 is a schematic exploded configuration diagram of an air curtain device and a space adjusting member in an embodiment of the present disclosure.

FIG. 8 is a schematic configuration diagram of an air curtain device in an embodiment of the present disclosure.

FIG. 9 is a schematic configuration diagram of an air curtain device in an embodiment of the present disclosure.

### DETAILED DESCRIPTION OF THE INVENTION

The technical content of the present disclosure will be further described in detail below in conjunction with embodiments and accompanying drawings. Those skilled in the art can understand the objectives, features, and effects of the present disclosure from the content disclosed in description. It is to be noted that the present disclosure can be implemented or applied through other different specific embodiments, and various modifications and changes can be made to each detail in the description based on different perspectives and applications without departing from the spirit of the present disclosure. The following embodiments will further detail relevant technical content of the present disclosure, but the disclosed content is not intended to limit the scope of the patent application for the present disclosure.

It is to be noted that terms such as "first", "second", and "third" used herein are intended to distinguish different elements, rather than to limit the elements themselves or to indicate a specific order of the elements. Furthermore, unless a specific quantity is indicated herein, the article "a/an" refers to one element or more than one element. Additionally, various steps described in the present application may be performed in sequence, in reverse sequence, or by appropriately altering or skipping steps during the control process.

In addition, the term "couple" described herein can be expressed as "directly connected" and/or "indirectly connected". Specifically, "the first element is configured to be coupled with the second element" may be expressed as "the first element is configured to be directly connected to the second element" and/or "the first element is configured to be indirectly connected to the second element". Moreover, it is to be noted that the terms "up", "down", "left", "right", "front", "back", etc. described herein are merely exemplary descriptions of relative directions, and the reference direction can be changed arbitrarily, not limited to absolute directions.

To facilitate understanding, three-dimensional schematic diagrams at different view angles, schematic exploded configuration diagrams, schematic sectional diagrams and the like of the air curtain device according to embodiments of the present disclosure will be described below.

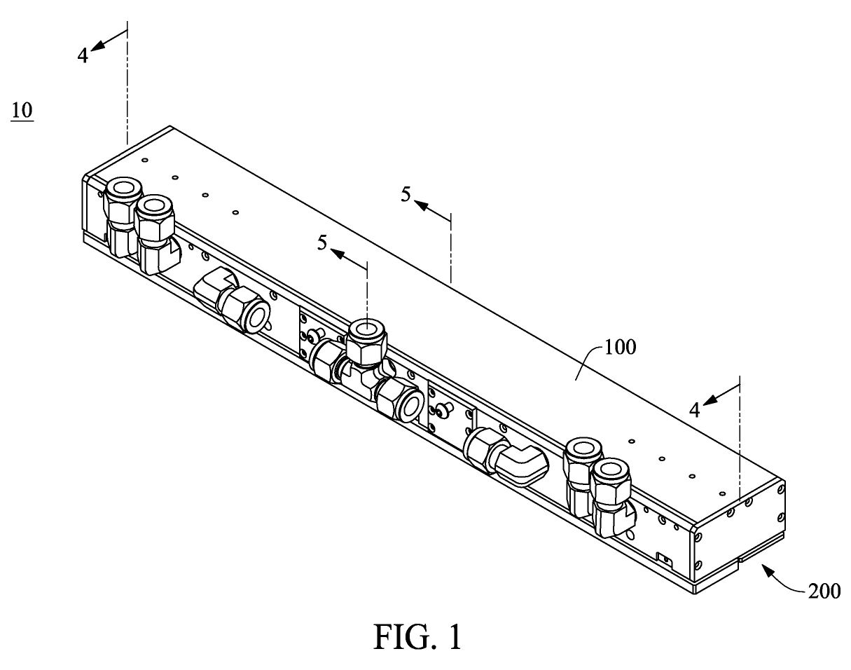

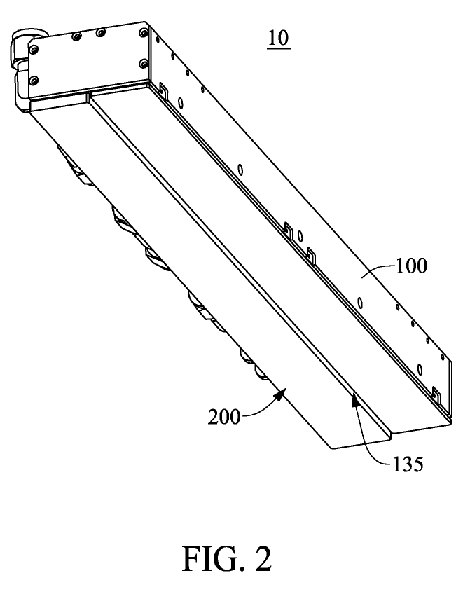

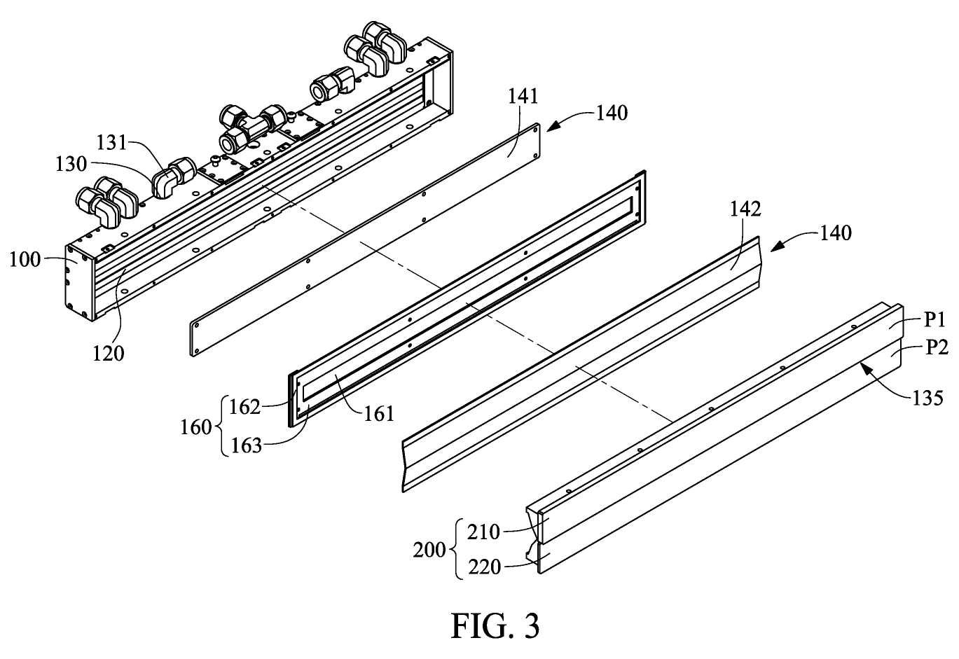

FIG. 1 is a three-dimensional schematic diagram of an air curtain device in an embodiment of the present disclosure; FIG. 2 is a three-dimensional schematic diagram of an air curtain device at another view angle in an embodiment of the present disclosure; and FIG. 3 is a three-dimensional schematic exploded configuration diagram of an air curtain device in an embodiment of the present disclosure.

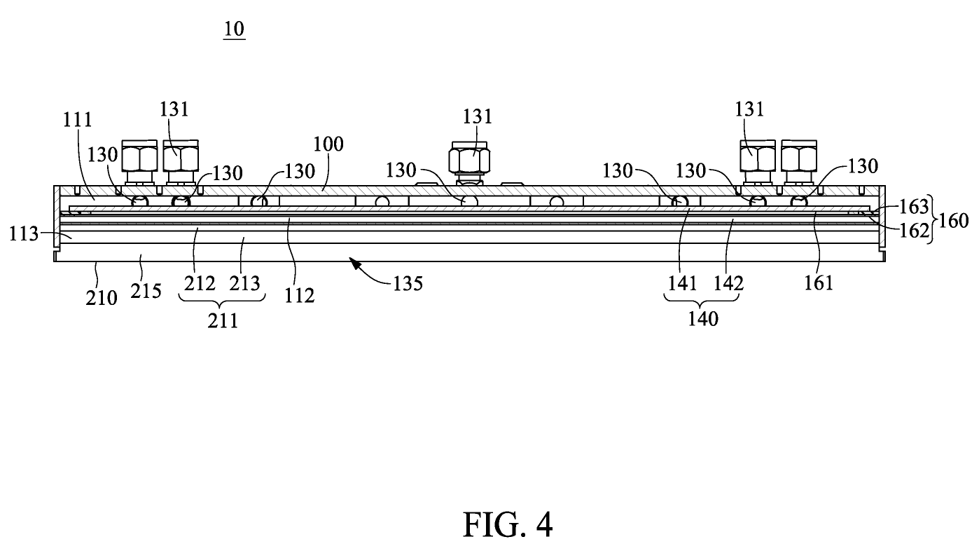

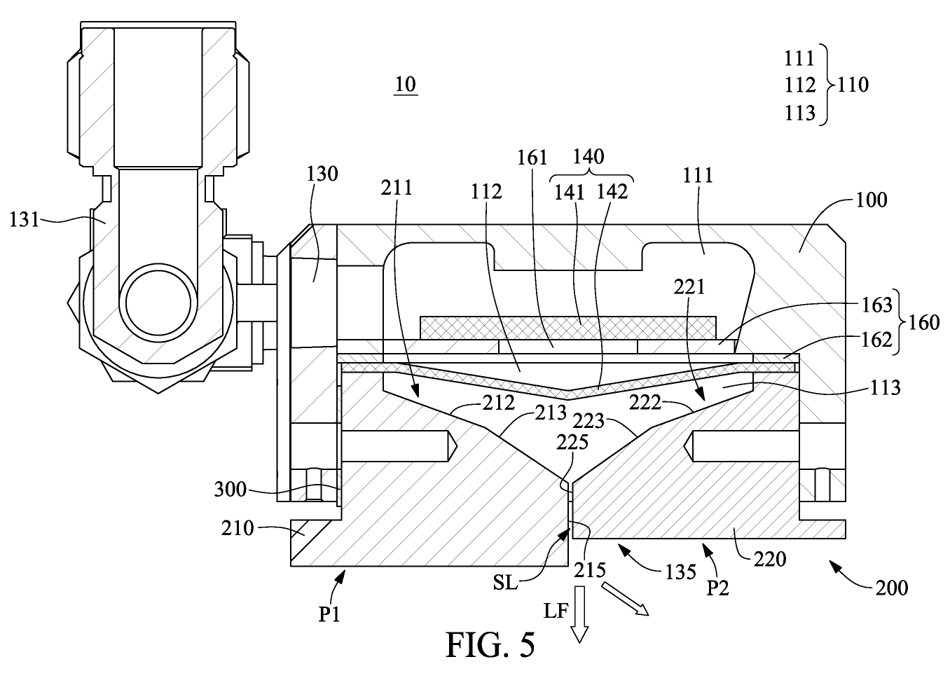

FIG. 4 is a schematic sectional diagram along a section line 4-4 in FIG. 1; and FIG. 5 is a schematic sectional diagram along a section line 5-5 in FIG. 1. It is to be noted that the length, configuration, dimension, position and the like of each element in the diagrams herein are only examples, and it is not limited to them.

With reference to FIG. 1, in an aspect, the present disclosure provides an air curtain device 10 which is suitable for a loading device (not shown in FIG. 1) of a semiconductor carrier, such as a loading device and a processing device of a wafer transfer box, a photomask transfer box, a carrier plate transfer box or carriers of other elements in a semiconductor manufacturing process, but not limited thereto.

With reference to both FIGS. 1 and 2 , FIG. 1 is a three-dimensional schematic diagram of the air curtain device 10 at one view angle in an embodiment, and FIG. 2 is a three-dimensional schematic diagram of the air curtain device 10 at another view angle in an embodiment. In one embodiment, the air curtain device 10 includes a housing 100 and an air curtain assembly 200. The housing 100 may be roughly in a long rectangular shape, for example. The air curtain assembly 200 may be, for example, positioned on one surface of the air curtain device 10 and forms an air outlet 135. The air curtain assembly 200 and the air outlet 135 thereof may, for example, extend in a long edge direction of the housing 100, thus the air curtain device 10 can provide a linear airflow with the same range as the long edge of the housing 100, thereby forming an air knife and an air curtain with specific length. However, the shape and configuration are only exemplary, and the configuration of the air curtain assembly 200 relative to the housing 100 is not limited thereto.

With reference to FIG. FIGS. 3, 4 and 5 together, the air curtain device 10 in the embodiment of the present disclosure is described with different schematic diagrams. FIG. 3 is a three-dimensional schematic exploded configuration diagram of the air curtain device 10 in an embodiment; FIG. 4 is a schematic sectional diagram along a section line 4-4 in FIG. 1; and FIG. 5 is a schematic sectional diagram along a section line 5-5 in FIG. 1. The housing 100 includes at least one air inlet 130, an accommodating space 120, and a plurality of air diffusion members 140. The plurality of air diffusion members 140 divide the accommodating space 120 into a plurality of air equalizing chambers 110. In this embodiment, the plurality of air diffusion members 140 include a first air diffusion member 141 and a second air diffusion member 142 which divide the accommodating space 120 into a first air equalizing chamber 111, a second air equalizing chamber 112, and a third air equalizing chamber 113. The number of the air diffusion members 140 may be set according to actual application demands, thereby achieving the area number of the divided air equalizing chambers 110.

In one embodiment, at least a part of the air curtain assembly 200 is adjacently arranged in one air equalizing chamber (such as the third air equalizing chamber 113 shown in FIG. 5) of the housing 100, and is defined as an air outlet 135. The air curtain assembly 200 includes at least two adjustable air curtains on different horizontal planes, such as a first adjustable air curtain 210 and a second adjustable air curtain 220, which are respectively positioned on a first plane P1 and a second plane P2. The first adjustable air curtain 210 and the second adjustable air curtain 220 are adjusted at a distance from each other to define a long and narrow space SL.

In one embodiment, the air curtain assembly 200 is configured to receive air that passes through the air equalizing chambers 110. After the air is subjected to adjusting, pressure storage, equalizing and diffusing by the plurality of air diffusion members 140 and the air equalizing chambers 110, and then is adjusted by the first adjustable air curtain 210, the second adjustable air curtain 220, and the long and narrow space SL between the first adjustable air curtain 210 and the second adjustable air curtain 220, a directional linear airflow LF will be formed. The linear airflow LF is suitable for blowing towards an opening (not shown in FIGS. 3 to 5) of the semiconductor carrier by means of the air outlet 135.

When air is supplied to enable the airflow to be charged into the accommodating space 120 of the housing 100 by means of the air inlet 130 of the air curtain device 10 in one embodiment of the present disclosure, the air can be blocked by the air diffusion members 140 to enable the airflow to be uniformly diffused in the air equalizing chambers 110. After reaching enough air pressure, the air is charged into another air equalizing chamber 110 by means of the air diffusion members 140. The airflow is well-distributed by means of the plurality of air equalizing chambers 110 and the plurality of air diffusion members 140. Because the air outlet 135 serves as a slot type air outlet 135 with the long and narrow space SL, the air in the third air equalizing chamber 113 is compressed through the slot type air outlet 135, the compressed air serves as power to be pushed to generate a high-speed and large-flow air curtain to blow downwards in a linear mode. Moreover, with the cooperation of the first plane P1 and the second plane P2 which are on different horizontal planes, for example, the height of the first plane P1 is larger than that of the second plane P2, the air curtain follows the smooth surface of the first plane P1 to be linearly rectified and blows towards the bottom end of the second plane P2 until reaching the opening of the semiconductor carrier, and therefore the air forms the directional linear airflow LF. In this way, linear airflow for blowing can be continuously provided when the semiconductor element is carried inside and outside the semiconductor carrier, which is conducive to truly blocking the fine dust and air with high moisture outside the semiconductor carrier, thereby improving the storage quality of the elements in the semiconductor carrier as well as improving the yield of the manufacturing process.

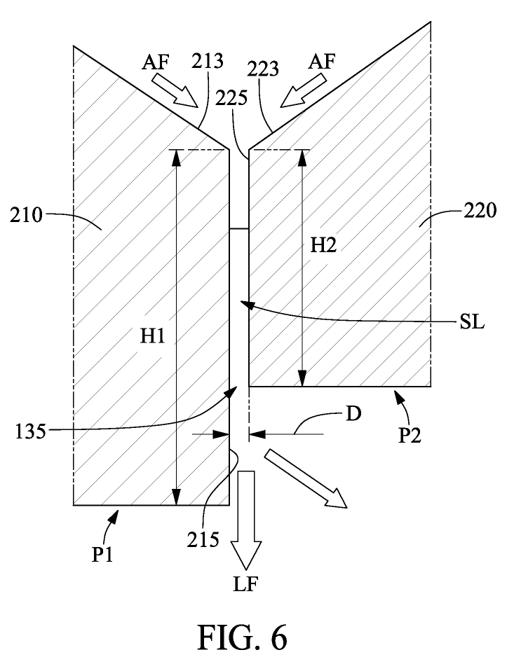

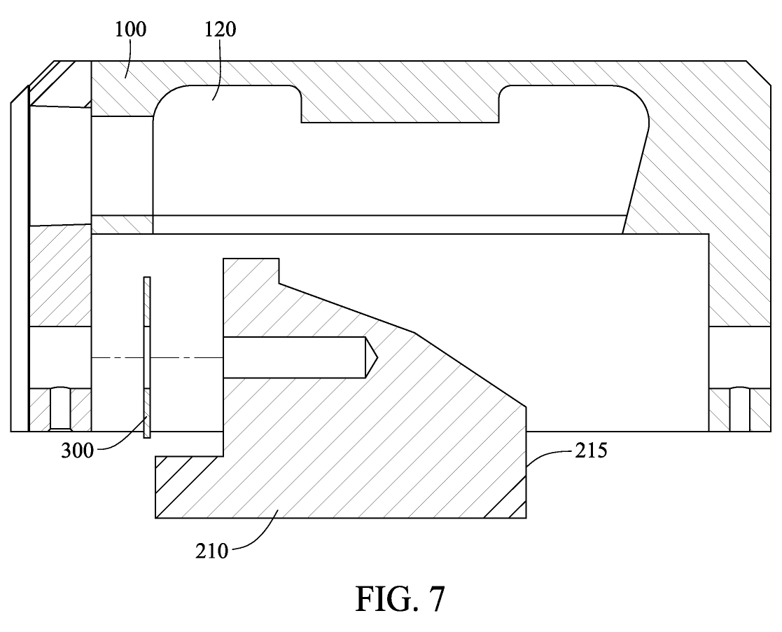

FIG. 6 is a partial enlarged schematic diagram of an air outlet of an air curtain device in an embodiment of the present disclosure; and FIG. 7 is a schematic exploded configuration diagram of an air curtain device and a space adjusting member in an embodiment of the present disclosure.

With reference to FIG. 6, in one embodiment, the first adjustable air curtain 210 is provided with the first plane P1, the second adjustable air curtain 220 is provided with the second plane P2, and a first side wall 215 of the first plane P1 and a second side wall 225 of the second plane P2 are different in wall surface height, for example, the first wall surface height H1 is larger than the second wall surface height H2. By means of the first adjustable air curtain 210 and the second adjustable air curtain 220 which are on different horizontal planes and are different in wall surface height, after the airflow AF flows out through the long and narrow space SL, the airflow may be compressed to flow along the side walls, a single side (such as the first plane P1) in the air outlet direction tends to be flat to obtain the linear airflow, and the second plane P2 is matched to form the directional linear airflow LF. By means of the above structural design, the problem that a conventional air curtain is directly diffused at the air outlet 135 can be solved.

Then, with reference to both FIGS. 6 and 7, in one embodiment, the air curtain device 10 further includes at least one space adjusting member 300 which is arranged in the accommodating space 120. The space adjusting member 300 is configured to adjust the first adjustable air curtain 210 and the second adjustable air curtain 220 at a distance from each other so as to define the range of the long and narrow space SL, namely, the space D between the first side wall 215 and the second side wall 225. The space adjusting member 300 may be arranged in a space between the adjustable air curtain and the housing 100. In this embodiment, the space adjusting member 300 is arranged on one side of the first adjustable air curtain 210. The first adjustable air curtain 210 and the second adjustable air curtain 220 are adjusted at a distance according to the thickness of the space adjusting member 300, and therefore the range (namely the space D) of the long and narrow space SL is adjustable. The space adjusting member 300 may be a gasket of different thicknesses or other forms of cushion bodies or the like, and may be detachably arranged on the housing 100 or arranged on the housing 100, and the number, the thickness or the cushion bodies of the space adjusting member 300 are set according to actual application requirements so that the range (namely the space D) of the long and narrow space SL can be adjusted at any time. In some embodiments, the housing 100 may be provided with screws, clamping and buckling members, sealing members and the like for adjusting and mounting the air curtain assembly 200 and/or the space adjusting member 300. In some embodiments, a mode of statically arranging the space adjusting member 300 to adjust the space D can avoid frictional particle pollution caused by a mechanism that can move at any time. By statically arranging the space adjusting member 300, possible air leakage of the air curtain device 10 and the housing 100 thereof can also be avoided, and overall stability as well as the service life can be improved and prolonged.

With reference to FIG. 5 again, the first adjustable air curtain 210 and the second adjustable air curtain 220 are provided with symmetrical slopes, and lower edges of the slopes correspond to the long and narrow space SL in position. A tapered structure is formed among the first adjustable air curtain 210, the second adjustable air curtain 220, and the third air equalizing chamber 113. In one embodiment, a first slope 211 is formed at the position, adjacent to the third air equalizing chamber 113, of the first adjustable air curtain 210. A second slope 221 is formed at the position, adjacent to the third air equalizing chamber 113, of the second adjustable air curtain 220. The first slope 211 and the second slope 221 are symmetrical slopes, such as a funnel-shaped tapered structure. The lower edges of the first slope 211 and the second slope 221 are adjacent to one end of the air outlet 135 of the long and narrow space SL. When air is started to be compressed by the funnel-shaped third air equalizing chamber 113 to be pushed into the long and narrow space SL till the air flows to the other end of the air outlet 135, by means of the symmetrical slopes of the adjustable air curtains, the air can be more uniform in the air equalizing chambers 110, and a more efficient air curtain can be provided for the semiconductor carrier with the airflow having the minimum speed loss and the maximum blowing and discharging thrust.

Besides the above structural design that the first slope 211 and the second slope 221 are symmetrical slopes, the first slope 211 of the first adjustable air curtain 210 further includes a first auxiliary slope 212 and a first main slope 213 which have different jump, and the first auxiliary slope 212 and the first main slope 213 are not coplanar. The second slope 221 of the second adjustable air curtain 220 further includes a second auxiliary slope 222 and a second main slope 223 which have different jump, and the second auxiliary slope 222 and the second main slope 223 are not coplanar. The first main slope 213 and the second main slope 223 are of a funnel-shaped tapered structure, and the lower edge of the first main slope 213 and the lower edge of the second main slope 223 are adjacent to one end of the air outlet 135 of the long and narrow space SL. When air passes through the main slope and the auxiliary slope which have different jump, the air in the third air equalizing chamber 113 is further compressed, and the air is compressed to be pushed into the long and narrow space SL till the air flows to the other end of the air outlet 135. Because of being guided by the sectional type slopes with different jump, the air is more uniform in the air equalizing chambers 110 and is more gathered and concentrated when it is close to the long and narrow space SL, thereby increasing the air outlet uniformity and air velocity.

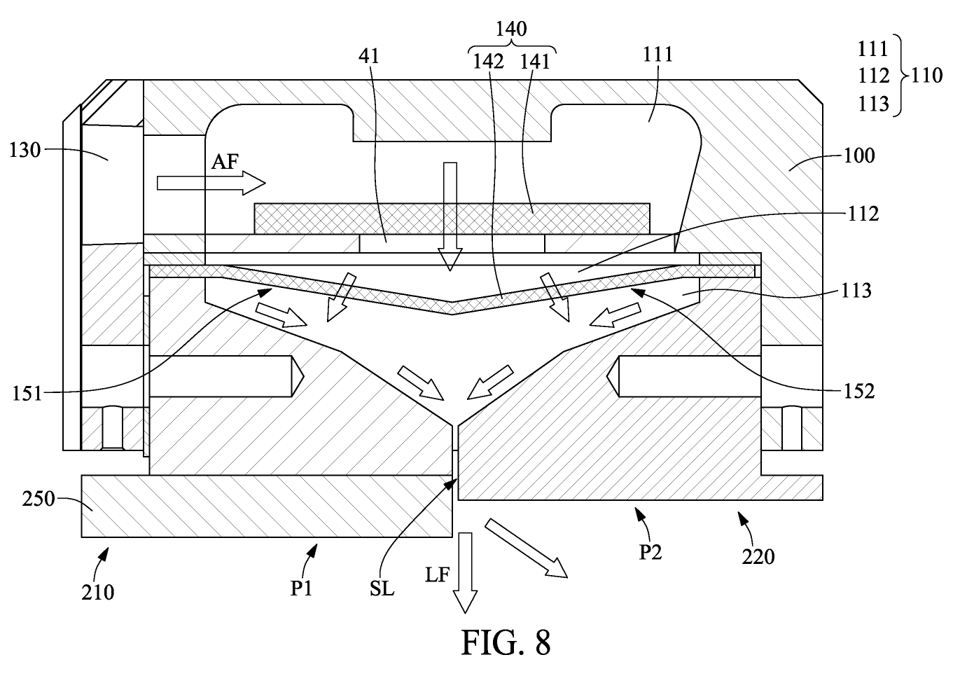

FIG. 8 is a schematic configuration diagram of an air curtain device in an embodiment of the present disclosure. The air diffusion member 140 adjacent to the air curtain assembly 200 may be used for dividing to form two air equalizing chambers 110, for example, the second air diffusion member 142 may be used for dividing to form the second air equalizing chamber 112 and the third air equalizing chamber 113. It is to be noted that the second air diffusion member 142 is provided with symmetrical slopes, such as a first diffusion slope 151 and a second diffusion slope 152, which form a similar V-shaped structure, and therefore the volume of air in the second air equalizing chamber 112 can be increased. Moreover, with the cooperation of the tapered structure among the first adjustable air curtain 210, the second adjustable air curtain 220, and the third air equalizing chamber 113, the volume of air in the third air equalizing chamber 113 can be increased. Due to above structural design, the volume of air in the air equalizing chamber can be increased, moreover, new air equalizing chambers can be obtained by dividing, which increases the diffusion area, and enhances the air diffusion effect.

With reference to FIG. 8, in one embodiment, the air curtain assembly 200 may further include at least one auxiliary air curtain 250 which is arranged below at least one of the first adjustable air curtain 210 and the second adjustable air curtain 220 so as to present the first plane P1 and the second plane P2 which are on different horizontal plane, namely, presenting the air outlet 135 with different first wall surface height H1 and second wall surface height H2, and therefore a directional air outlet effect can be provided. In one embodiment, the thickness of the auxiliary air curtain 250 (namely, the provided wall surface height) may be adjusted to be different according to needs. In one embodiment, the auxiliary air curtain 250 may have the same or different thicknesses, and is independently or separately arranged on each adjustable air curtain. It is to be noted that in response to the adjustment of the wall surface height of the adjustable air curtain (such as the first adjustable air curtain 210 or the second adjustable air curtain 220) of the air curtain assembly 200, different wall surface heights may be adjusted by means of integrally-formed adjustable air curtain with different sizes or by means of the arranged auxiliary air curtain 250. Thus, by means of the arranged auxiliary air curtain 250 and the assistance of the auxiliary air curtain in the elastic adjustment of the adjustable air curtains on the different wall surface heights of the air outlet 135, the air curtain device 10 may adjust the flowing condition of the linear airflow LF of the air outlet 135 according to needs, so as to make the airflow flat and linear and/or blow towards the side direction.

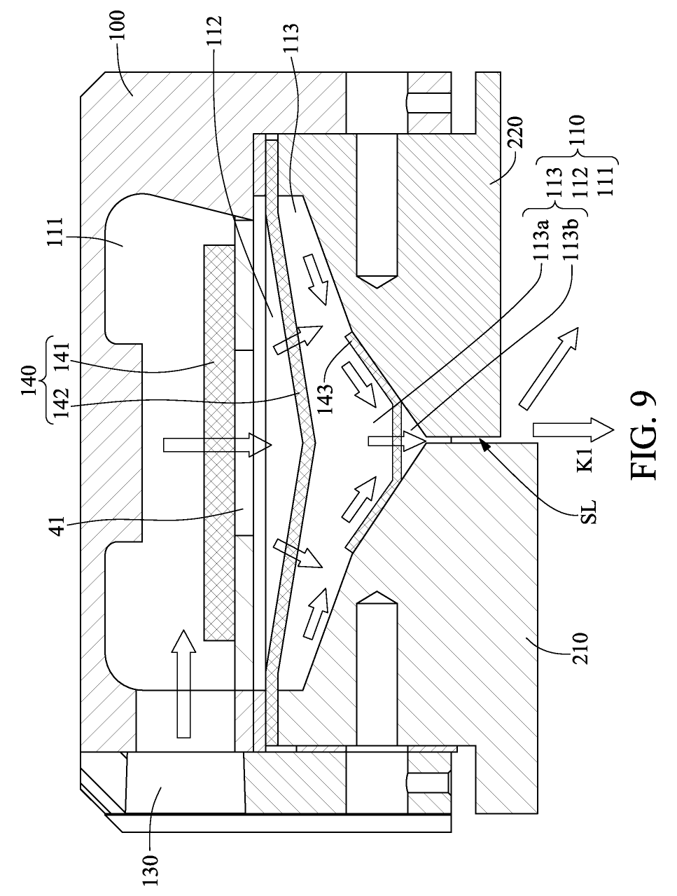

FIG. 9 is a schematic configuration diagram of an air curtain device in an embodiment of the present disclosure. The third air equalizing chamber 113 may further include an auxiliary air diffusion member, such as the third air diffusion member 143, and therefore, the third air equalizing chamber 113 is divided into two secondary air equalizing chambers, such as a first secondary air equalizing chamber 113a and a second secondary air equalizing chamber 113b. A partial structure of the third air diffusion member 143 is arranged in match with the first slope 211 of the first adjustable air curtain 210 and the second slope 221 of the second adjustable air curtain 220, and the other partial structure of the third air diffusion member 143 corresponds to one end of the air outlet 135, adjacent to the long and narrow space SL, of the lower edges of the first slope 211 and the second slope 221. By increasing the quantity of the auxiliary air diffusion members, the uniformity of air diffusion is relatively increased.

In the present disclosure, the materials of all the air diffusion members may be selected from a sintered filter screen, a diffuser, or breathable filter cotton.

With reference to FIG. 3 again, the air curtain device 10 may further include a plurality of air inlet elements 131 which are configured in different directions and different numbers, and the air inlet elements 131 are arranged on the housing 100. The air inlet elements 131 are in communication with the air inlet 130 to adjust different air inlet positions or air inflows. In some embodiments, one or more air inlets 130 may be provided in match with the air inlet elements 131 and are arranged at different positions on the housing 100 of the air curtain device 10. One air inlet element 131 may be in communication with the one or more air inlets 130. In some embodiments, the plurality of air inlet elements 131 may be in communication with the one or more air inlets 130. Thus, by means of diversified arrangement of the one or more air inlet elements 131, including various directions, positions, lengths, and pipe diameters, and communicating with the different air inlets 130, and in response to the different design requirements of different air inlets 130 (for example, different space, mounting orientation and/or pipeline configuration requirements for making the air curtain device 10 match a semiconductor device), the requirements for reducing airflow attenuation, and optimizing airflow paths, and the requirements for adjusting different air flow rates, air pressures, and air velocities, the air inlet elements 131 are subjected to different configurations. Therefore, the time difference, flow path, velocity, flow rate and the like of airflow paths of the inputted air may be adjusted according to different requirements, so as to reduce air flowing, strokes and energy consumption, moreover, the uniformity and the quality of the linear airflow provided by the air curtain device 10 can be further improved, and various parameters of the linear airflow can be adjusted by the configuration of the air inlet elements 131 and the air inlets 130.

With reference to FIG. 3 again, in one embodiment, the housing 100 further internally includes spacers 160, and the spacers 160 serve as a space partition and can also serve as supporting carriers of the air diffusion members 140. In one embodiment, the spacers 160 are provided with long open holes 161 for communicating the first air equalizing chamber 111 with the second air equalizing chamber 112, and the spacers 160 may be covered with the air diffusion members 140. In one embodiment, the spacers 160 include frames 162 and sheets 163. The length of the spacers 160 in the accommodating space 120 is approximately equal to that of the housing 100. Moreover, the long open holes 161 are formed in two ends of the sheets 163 in the length direction of the housing 100, and thus the airflow charged into the first air equalizing chamber 111 may be uniformly charged into the second air equalizing chamber 112 by means of the long open holes 161.

Thus, by means of the plurality of air diffusion members, the plurality of air equalizing chambers, and the adjustable air curtains of the air curtain assembly of the air curtain device according to the present disclosure, the air outlets with different slope segment differences, different horizontal planes, and different spaces can be adjusted, thus the airflow can be adjusted, and the directional linear airflow can be provided.

When supplied air is charged into the accommodating space of the housing by means of the air inlet, the air is blocked by the air diffusion members, so that the airflow can be uniformly diffused in the air equalizing chambers, and after reaching enough air pressure, the air is charged into another air equalizing chamber by means of the air diffusion members. Moreover, the airflow can be repeatedly equalized by the plurality of air equalizing chambers and the plurality of air diffusion members, and then the adjustable air curtain assembly with different horizontal planes and different long and narrow spaces is used as the air outlet for airflow adjustment, so that the outputted air forms the directional linear airflow. Therefore, uniform and linear air with concentrated air volume is outputted, moreover, the airflow direction can be adjusted, energy loss can be reduced, and turbulence and dispersion of the airflow in the flowing direction can be reduced. When the semiconductor element is carried inside and outside the semiconductor carrier, a linear air curtain in a laminar flow state can be continuously provided for closure, which is conducive to isolating the fine dust and air with high moisture outside, thereby improving the storage quality of the element in the semiconductor carrier, furthermore, the yield of the manufacturing process is improved, and the effect of energy conservation is achieved.

The present disclosure is disclosed above with the embodiments; however, those skilled in the art should understand that the embodiments are only for illustrating the present disclosure and should not be interpreted as limiting the scope of the present disclosure. It is to be noted that any changes and substitutions that are equivalent to the embodiments should be considered to be included within the scope of the present disclosure. Therefore, the protection scope of the present disclosure shall be defined by claims, and the scope of the attached claims should be interpreted in the broadest sense to encompass all modifications, similar arrangements, and processes.

While the present disclosure has been described by means of specific embodiments, numerous modifications and variations could be made thereto by those skilled in the art without departing from the scope and spirit of the present disclosure set forth in the claims.

What is claimed is:

1. An air curtain device, suitable for a loading device of a semiconductor carrier, comprising:
a housing, including at least one air inlet, an accommodating space, and a plurality of air diffusion members, the air inlet being in communication with the accommodating space, and the plurality of air diffusion members dividing the accommodating space into a plurality of air equalizing chambers; and
an air curtain assembly, adjacently arranged in one of the air equalizing chambers of the housing and defined as an air outlet, the air curtain assembly including at least two adjustable air curtains on different horizontal planes, and the two adjustable air curtains being adjusted at a distance from each other to define a long and narrow space,
wherein the air curtain assembly is configured to receive air that passes through the air equalizing chambers; and after the air is adjusted by the long and narrow space and the two adjustable air curtains, a directional linear airflow is formed, and the linear airflow is suitable for blowing towards an opening of the semiconductor carrier.

2. The air curtain device according to claim 1, further comprising at least one space adjusting member, arranged in the accommodating space, the space adjusting member being configured to adjust a range of the long and narrow space between the two adjustable air curtains.

3. The air curtain device according to claim 1, wherein the two adjustable air curtains are provided with symmetrical slopes, lower edges of the slopes correspond to the long and narrow space in position, and a tapered structure is formed between the two adjustable air curtains and the air equalizing chambers.

4. The air curtain device according to claim 1, wherein the two adjustable air curtains are respectively provided with at least two slopes with different jump, lower edges of the slopes correspond to the long and narrow space in position, and a tapered structure is formed between the two adjustable air curtains and the air equalizing chambers.

5. The air curtain device according to claim 1, wherein the air diffusion member adjacent to the air curtain assembly is provided with symmetrical slopes so that an air volume of two air equalizing chambers divided by the air diffusion member is increased.

6. The air curtain device according to claim 1, wherein the air curtain assembly further comprises at least one auxiliary air curtain, arranged below at least one adjustable air curtain so as to present the two adjustable air curtains on different horizontal planes.

7. The air curtain device according to claim 1, wherein two air diffusion members are provided and are arranged at an interval in the accommodating space, and a first air equalizing chamber, a second air equalizing chamber, and a third air equalizing chamber are sequentially divided from a position adjacent to the air inlet; the air is diffused by each air diffusion member to form an air-equalized airflow and flows into the second air equalizing chamber and the third air equalizing chamber; and the air curtain assembly is adjacently arranged in the third air equalizing chamber.

8. The air curtain device according to claim 7, wherein the third air equalizing chamber further comprises an auxiliary air diffusion member so that the third air equalizing chamber is divided into two secondary air equalizing chambers.

9. The air curtain device according to claim 1, wherein materials of the air diffusion members are selected from a sintered filter screen, a diffuser, or breathable filter cotton.

10. The air curtain device according to claim 1, further comprising a plurality of air inlet elements configured in different directions and arranged on the housing, the air inlet elements being in communication with the air inlet to adjust different air inlet positions or air inflows.
